(19) United States
(12) Patent Application Publication
(10) Pub. No.: US 2021/0092845 A1
(43) Pub. Date: Mar. 25, 2021

(54) CONNECTING CIRCUIT BOARDS USING FUNCTIONAL COMPONENTS

(71) Applicant: Hewlett-Packard Development Company, L.P., Spring, TX (US)

(72) Inventors: Dan Rothenbuhler, Boise, ID (US); Dean Richtsmeier, Boise, ID (US)

(21) Appl. No.: 16/498,976

(22) PCT Filed: Apr. 13, 2017
(86) PCT No.: PCT/US2017/027477

§ 371 Date: Sep. 27, 2019

(51) Int. Cl. H05K 1/14; H05K 1/11; H05K 1/02

(52) U.S. Cl. CPC H05K 1/144; H05K 1/0206; H05K 1/116

(57) ABSTRACT

A circuit board assembly, the assembly including: a first circuit board; a second circuit board; and a functional component with a first side and a second side opposite the first side, the functional component comprising an electrical pathway between the first circuit board and the second circuit board, wherein the functional component provides a circuit element in addition to the electrical pathway between the first circuit board and the second circuit board, the first side of the functional component is connected to the first circuit board, the second side of the functional component is connected to the second circuit board, and the functional component mechanically couples the second circuit board.

### BACKGROUND

Printed circuit boards (“PCBs”) are substrates with conductive traces which connect a variety of electronic components. The components, such as integrated circuits, capacitors, inductors, etc. are added to the board to provide the desired functionality. Such a functionalized board is called a printed circuit assembly (“PCA”). Printed circuit boards and assemblies may be produced with a variety of processes; these different processes have different costs and different limitations.

### BRIEF DESCRIPTION OF THE DRAWINGS

The accompanying drawings illustrate various examples of the principles described herein and are a part of the specification. The illustrated examples do not limit the scope of the claims.

FIG. 1 shows a side view of a circuit board assembly according to one example consistent with the present disclosure.

FIG. 2 shows a side view of a circuit board assembly according to one example consistent with the present disclosure.

FIG. 3 shows a top view of a circuit board assembly according to one example consistent with the present disclosure.

FIG. 4 shows a top view of a circuit board assembly according to one example consistent with the present disclosure.

FIG. 5 shows a side view of a circuit board assembly according to one example consistent with the present disclosure.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

Forming assemblies of multiple circuit boards may be desirable for a variety of reasons, for example, the use of multiple boards allows different specifications and different manufacturing processes to be used with different portions of a circuit. However, splitting components onto multiple boards may use some communication between the circuit boards. Further, the multiple boards may need to be attached together.

Many PCAs include functional components that extend from the circuit board. These functional components may limit how close multiple boards may be placed to each other.

Relatively tall functional components may be used to provide mechanical connection and signal transmission between adjacent boards while still providing their functional capabilities to a circuit on either and/or both boards. Tall functional components are available at reasonable prices, often prices lower than dedicated board-to-board connections. In some examples, the functional component provides functional capabilities to both circuit boards.

This specification describes using functional components to provide board-to-board connections in a multiple board circuit board assembly. The use of functional components may reduce costs compared with other board-to-board connectors. The use of functional components may reduce the number of components in a multiple board assembly. The use of functional components may reduce the number of types of parts used in an assembly and therefore in inventory.

Among other examples, a circuit board assembly, the assembly including: a first circuit board; a second circuit board; and a functional component with a first side and a second side opposite the first side, the functional component comprising an electrical pathway between the first circuit board and the second circuit board, wherein the functional component provides a circuit element in addition to the electrical pathway between the first circuit board and the second circuit board, the first side of the functional component is connected to the first circuit board, the second side of the functional component is connected to the second circuit board, and the functional component mechanically couples the second circuit board.

Among other examples, this specification also describes a circuit board assembly, the assembly including: a first circuit board; a second circuit board; and a functional component with a first side and a second side opposite the first side, the functional component providing a circuit element other than an electrical pathway between the first circuit board and the second circuit board, wherein the circuit element is provided to a circuit on the first circuit board, the first side of the functional component is connected to the first circuit board, the second side of the functional component is connected to the second circuit board, and the functional component mechanically couples the second circuit board.

This specification describes a circuit board assembly including: a first circuit board; a second circuit board; and a plurality of functional components, each functional component mounted to the first circuit board and second circuit board, wherein the functional components mechanically couple the second circuit board and functional components are located at opposite edges of the second circuit board.

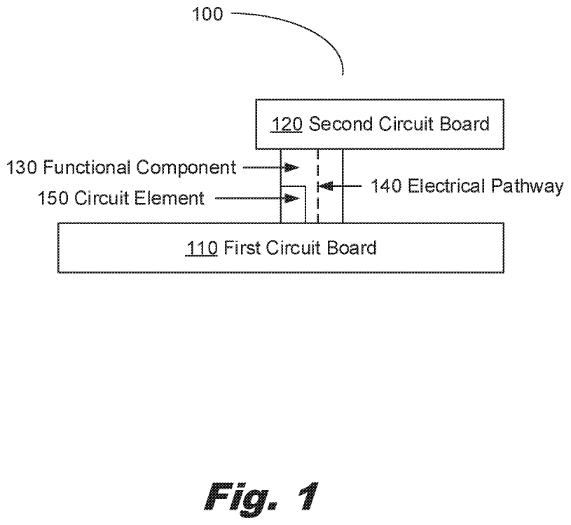

Turning now to the figures, FIG. 1 shows a side view of a circuit board assembly (100) according to one example consistent with the present disclosure. The assembly (100) including: a first circuit board (110); a second circuit board (120); and a functional component (130) with a first side and a second side opposite the first side, the functional component comprising an electrical pathway (140) between the first circuit board (110) and the second circuit board (120), wherein the functional component (130) provides a circuit element (150) in addition to the electrical pathway (140) between the first circuit board (110) and the second circuit board (120), the first side of the functional component (130) is connected to the first circuit board (110), the second side of the functional component (130) is connected to the second circuit board (120), and the functional component (130) mechanically couples the second circuit board (120).

The assembly (100) is a circuit board assembly that includes a first circuit board (110) and a second circuit board (120). The use of a multi-circuit board assembly (100) has some advantages over a single board assembly. The use of multiple circuit boards allows the use of circuit boards produced with different processes. For example, the first circuit board (110) may be produced with a lower feature resolution and the second circuit board (120) may be produced with a higher feature resolution. The first circuit board (110) may be produced with a first process and the second circuit board (120) may be produced with a second process. By allocating different components to circuit boards with different characteristics, improved performance and/or reduced costs can be obtained compared with using a uniform board.

In some examples, the first circuit board (110) and the second circuit board (120) use different voltages. This may result in different feature separations on the first circuit board (110) and the second circuit board (120). This may use different processes on the first circuit board (110) and second circuit board (120). The first circuit board (110) may have a different number of layers than the second circuit board (120). The first circuit board (110) may be fabricated from different materials than the second circuit board (120). The ability to mix and match properties of the first and second circuit boards (110, 120) allows more design options compared with single board designs.

The use of multiple circuit boards also increases thickness while reducing length and/or width of the assembly (100).

The use of multiple circuit boards has drawbacks. For example, power and signals are provided to both the first and second circuit boards (110, 120). Similarly, in almost all cases, signals will need to be exchanged between the first circuit board (110) and second circuit board (120). These increased number of connections between the boards (110, 120) as well as the reliability of such connects are factors to consider when balancing the tradeoff between single board and multiple board designs.

The first circuit board (110) includes electrical components on a substrate. The first circuit board (110) may be produced using a wide variety of processes, for example, printing, screen printing, etching, photo masking, etc. The first circuit board (110) may include attached electronic components, for example: capacitors, inductors, integrated circuits, etc. A portion of the first circuit board (110) and second circuit board overlap in the assembly (100). Accordingly, components that would contact the second circuit board (120) if within the overlap may be located outside the overlap, reducing the overall depth of the final assembly and allowing the use of components which are taller than the component (130) used to connect the first and second circuit boards (110, 120).

In some examples, the first circuit board (110) has a larger length and/or width than the second circuit board (120). In some examples, the first and second circuit boards (110, 120) may have the same length and width. In some examples, the first and second circuit boards (110, 120) may be offset from each other, for example, two boards may have a portion of the width of one board extending beyond the other board, where the extending portion includes features to connect the board to external components and/or systems.

Second circuit board (120) may be similar to the first circuit board (110). As discussed above, using different processes and/or feature sizes for the first and second circuit boards (110, 120) may allow additional design efficiencies. However, the use a first and second circuit board (110, 120) with the same characteristics is also useful, for example, to reduce a length and/or width of the assembly (100).

In some examples, the first circuit board (110) and the second circuit board (120) are different sizes. For example, the second circuit board (120) may be smaller than the first circuit board (110).

The electrical component (130) is a component with some height above the circuit board (110). The electrical component is sufficiently high to allow the first circuit board and second circuit board (120) to be mounted separated by the height of the electrical component (130) without unintended and/or undesired contacts between the circuit boards (110, 120).

A variety of electrical components (130) are useful for making the described assemblies (100). The electrical component (130) may be selected from a group that includes: capacitors, inductors, resistors, surface-mount ferrites, etc. The electrical component (130) provides a mechanical connection between the first circuit board (110) and the second circuit board (120). The electrical component provides an electrical pathway (140) between the first circuit board (110) and the second circuit board (120).

The electrical component (130) may include a contact point where an electrical connection is made. In some examples, a contact point serves as the electrical pathway (140) between the first circuit board (110) and the second circuit board (120). For example, if the electrical component (130) is a capacitor with contact points covering opposite surface, the capacitor may be positioned so that the contact points extend from the first circuit board (110) to the second circuit board (120). Electrical contact may be made with a contact on both circuit boards (110, 120) to create an electrical pathway (140) between the first and second circuit boards (110, 120). Similarly, the other contact may be used to generate a second electrical pathway (140) that is separated from the first by the capacitor.

The electrical pathway (140) is electrical connection between the first circuit board (110) and the second circuit board (120) that uses the electrical component (130) but does not significantly modify the signal provided. Thus, this includes electrical traces, wires, conductors, etc. that include some theoretical resistance but are practically treated as equal potential locations. While recognizing that all real world conductors have resistance and loss, this distinction recognizes the difference between, for example, a resistor and a wire.

The electrical pathway (140) may be formed using a contact for the electrical component (130). The electrical pathway (140) may be added to the electrical component (130). A plurality of electrical pathways may be added to an electrical component (130) to provide additional signals between the first circuit board (110) and the second circuit board (120). For example, an inductor coil may be provided with an additional conductive trace extending from one side of the coil to the other side of the coil. The trace may then be connected to electrical conductors on the first and second circuit boards (110, 120), for example, using solder. The electrical contacts to the circuit element of the coil may be connected to the first circuit board (110) and/or second circuit board (120).

The circuit element (150) is provided by the electrical component (130) and is something other than merely providing an electrical contact between the first circuit board (110) and the second circuit board (120). Preferably, the circuit element (150) is a circuit element that would otherwise be used on one and/or both of the circuit boards (110, 120). In this way, the electrical component (130) provides: a mechanical connection between the first circuit board (110) and the second circuit board (120), an electrical pathway (140) between the first circuit board (110) and the second circuit board (120); and the circuit element (150) for use by one and/or both of the circuit boards (110, 120). In another example, the circuit element (150) may be provided to support an off board operation. The circuit element (150) may be provided on an electrical pathway between the first circuit board (110) and the second circuit board (120). For example, resistors and/or capacitors are frequently used to separate portions of electronic systems.

In some examples, the functional component (130) is a capacitor, a surface-mount ferrite, a resistor, and/or an inductor. The functional component (130) may include a plurality of independent electrical pathways (140) between the first circuit board (110) and the second circuit board (120). The electrical pathways (140) may include contact points to the functional component (130). The electrical pathways may be independent of the contact points to the functional component (130).

The assembly (100) may include a plurality of functional components, wherein the functional components of the plurality of functional components are connected to both the first circuit board and the second circuit board. For example, the first circuit board (110) and the second circuit board (120) may be connected using two, three, four, five, six, or more functional components (130). In some examples, the functional components (130) are all the same functional component (130); for example, the functional components (130) are all resistors. The functional components (130) may all be the same width, i.e., the dimension between the first and second circuit boards (110, 120). This may facilitate making the first and second circuit boards (110, 120) parallel to each other. The functional components (130) may be located near opposite edges of the second circuit board (120). For example, the functional components (130) may be within 1 centimeter of an edge of the second circuit board (120). The functional components (130) may overlap the edge of the second circuit board (120). For example, the second circuit board (120) may contact half of a surface of the functional component (130). This approach may facilitate forming the connection between the functional component (130) and the second circuit board (120) easier by allowing access to the area to be connected.

The functional component (130) may include flat surfaces on opposite sides of the functional component (130). The flat surfaces may be used to attach the respective sides to the first and second circuit boards (110, 120). For example, solder may be used to attach the flat surfaces to the first circuit board (110) and the second circuit board (120). The flat surface may be treated with solder and attached to a conductive pad on a circuit board (110, 120). Each of the plurality of functional components (130) may provide a circuit element (150) used by a circuit board (110, 120). In some examples the functional components (130) couples the first circuit board (110) and second circuit board (120). In some examples, the functional component (130) supports the second circuit board (120) with respect to the first circuit board (110).

The first and/or second circuit board (110, 120) may include a window to facilitate attachment of the functional component (130). The window provides access to, for example, provide solder, provide heat to reflow solder, apply a conductive epoxy, etc.

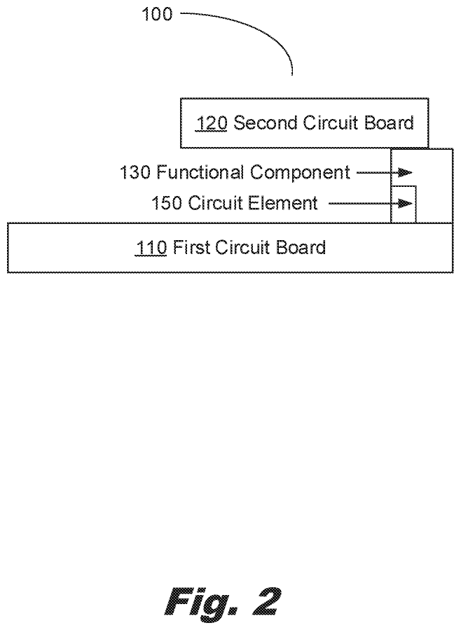

FIG. 2 shows a side view of a circuit board assembly (100) according to one example consistent with the present disclosure. The assembly (100) includes: a first circuit board (110); a second circuit board (120); and a functional component (130) with a first side and a second side opposite the first side, the functional component providing a circuit element (150) other than an electrical pathway between the first circuit board (110) and the second circuit board (120), wherein the circuit element (150) is provided to a circuit on the first circuit board (110), the first side of the functional component (130) is connected to the first circuit board (110), the second side of the functional component (130) is connected to the second circuit board (120), and the functional component (130) mechanically couples the second circuit board (120).

This assembly (100) still uses a functional component (130) to provide a mechanical linkage between the first and second circuit boards (110, 120). The functional component (130) also provides a circuit element (150). However, the functional component (130) in this example does not provide a separate electrical pathway (140) between the first and second circuit boards (110, 120). Electrical pathways (140) may be provided by other components on the boards (110, 120). Electrical pathways may be provided through a third component, for example, a processor independently connected to both the first and second board (110, 120).

The first circuit board (110) and second circuit board (120) have been discussed above. The approach described in this specification is compatible with a wide range of circuit board types produces with a variety of processes. The functional component (130) may be selected depending on circuit needs and the downstream processing of the assembly (100).

The functional component (130) may extend from the circuit board (110, 120) further than any other component on the circuit board (110, 120). In some examples, components which extend further may be located in regions where the circuit boards (110, 120) don't overlap. Similarly, other components may be arranged to prevent mechanical contact and/or proximity between components on the first circuit board (110) and the second circuit board (120).

The use of a functional component (130) that includes an electrical pathway (140) is described under FIG. 1, above. In contrast, FIG. 2 describes a functional component that provides a circuit element (150) as well as a mechanical connection between the first circuit board (110) and the second circuit board (120). In some examples the functional components (130) couples the first circuit board (110) and second circuit board (120). In some examples, the functional component (130) supports the second circuit board (120) with respect to the first circuit board (110).

The circuit element (150) is the function of the functional component (130). The circuit element modifies an electrical signal and/or performs some other purpose on the first circuit board (110) and/or second circuit board (120) besides transmitting an electrical signal. The use of the functional component to provide a circuit element (150) in addition to providing the mechanical connection between the first circuit board (110) and the second circuit board (120) allows a reduction in the number of components used in the assembly (100).

In some examples, the assembly (100) further comprises a plurality of functional components (130), each of the functional components (130) providing a circuit element (150) other than an electrical pathway (140) between the first circuit board (110) and the second circuit board (120).

The assembly (100) may include a plurality of types of functional components (130), e.g., light emitting diodes (LEDs) and capacitors. The assembly (100) may use a plurality of functional components of a common type, e.g., different colors of LEDs. The assembly (100) may include a plurality of components with the same specification, e.g., all 10 kilo-ohm resistors. The use of the same type of functional component (130) may facilitate having a common height to support the separation for the first and second circuit boards (110, 120).

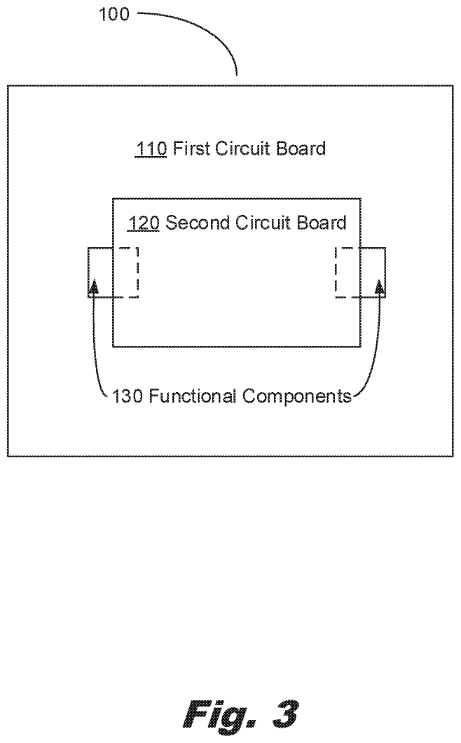

FIG. 3 shows a top view of a circuit board assembly (100) according to one example consistent with the present disclosure. The circuit board assembly (100) includes; a first circuit board (110); a second circuit board (120); and a plurality of functional components (130), each functional component (130) mounted to the first circuit board (110) and second circuit board (120), wherein the functional components (130) mechanically couples the second circuit board (120) and functional components (130) are located at opposite edges of the second circuit board (120).

In some examples, the functional components (130) each provide multiple electrical connections between the first circuit board (110) and the second circuit board (120). For example, an input to the functional component (130) may be connected to both the first circuit board (110) and the second circuit board (120). Similarly, an output from the functional component (130) may be connected to both the first circuit board (110) and the second circuit board (120). Some functional components (130) include pads and/or other contact points that can be used as bridging conductors between the first circuit board (110) and the second circuit board (120).

The first circuit board (110) may have a lower feature resolution than the second circuit board (120). The use of different processes, specification, and features is one advantage of using a first (110) and second circuit board (120).

A variety of techniques can be used to attach the functional components (130) to the second circuit board (120). In some examples, selective soldering is used to selectively connect the functional components (130) without disturbing other soldered components.

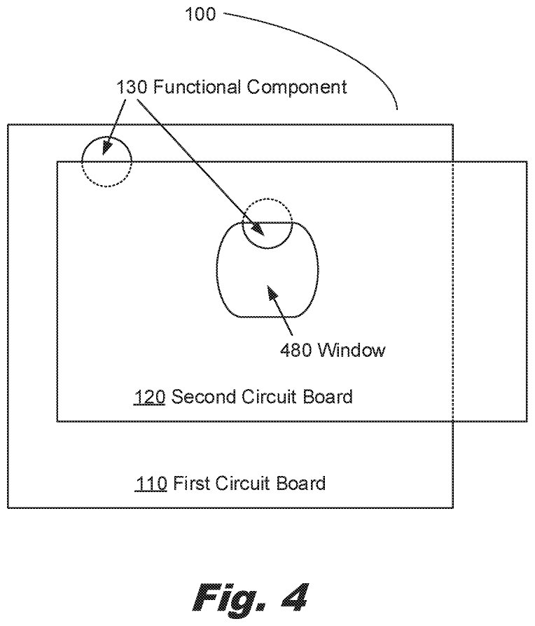

FIG. 4 shows a top view of a circuit board assembly (100) according to one example consistent with the present disclosure. This assembly (100) includes; a first circuit board (110); a second circuit board (120); functional components (130) attached to both the first circuit board (110) and second circuit board (120); and an opening (480) in the second circuit board (120) allowing access to a functional component (130).

The opening (480) may be in the first circuit board (110). The opening (480) may be in the second circuit board (120). Both circuit boards (110, 120) may include openings (480). A circuit board may include multiple openings (480). In some examples, there is an opening (480) for each functional component (130) located away from an edge of the circuit board (110, 120). An opening (480) may allow access to multiple functional components (130).

The opening (480) facilitates connecting the functional component (130) to the circuit board (110, 120) containing the opening (480). The opening may be used to provide solder to connect the functional component (130) to the circuit board (110, 120) containing the opening (480). The opening may be used to provide a conductive epoxy to connect the functional component (130) to the circuit board (110, 120) containing the opening (480). The opening may be used to allow a heat source to liquefy a solder to form a connection between the functional component (130) and the circuit board (120) containing the opening (480). The heat source may be an iron. The heat source may be a radiation source, for example, an IR source. The heat source may be a hot air pencil.

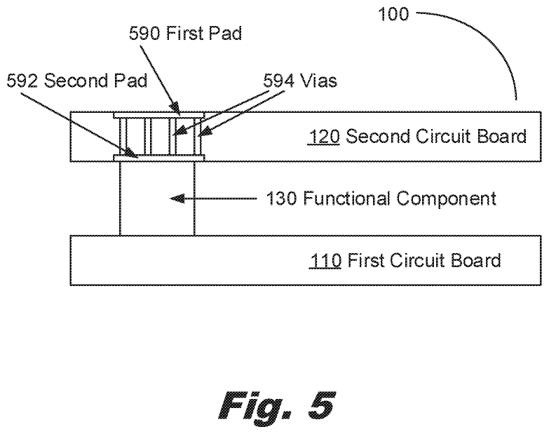

FIG. 5 shows a side view of a circuit board assembly (100) according to one example consistent with the present disclosure. This assembly (100) includes: a first circuit board (110); a second circuit board (120); a functional component (130) connecting the first and second circuit boards (110, 120); a first pad (590) on a surface of the second circuit board (120) opposite the point of contact of the functional component (130); a second pad (592) on a surface of the second circuit board (120) at the point of contact with the functional component (130); and a plurality of vias (594) connecting the first pad (590) and the second pad (592).

In some cases, attaching functional components to a second circuit board (120) when the functional components (130) are located away (e.g., more than 1 cm) from an edge of the second circuit board (120) may be difficult. One solution is to place solder on the second pad (592). Solder may be placed on a top surface of a functional component (130). The top surface of the functional component (130) is then brought into contact and/or proximity to the second pad (592) on the second circuit board (120). The second pad (592) is thermally conductive. The second pad (592) may be electrically conductive, for example, the second pad (592) may form an electrical connection to the functional component (130). The second pad (592) is connected to a first pad (590) by a plurality of vias (594). The first pad (590) and the vias (594) are thermally conductive. The first pad (590) and the vias (594) may be electrically conductive. For example, the first and second pads (590, 592) and vias (594) may contain copper, silver, gold, aluminum, nickel, tin, and/or other metals. In some examples, the pads (590, 592) and vias (594) metalized by immersion plating. The vias may be made thermally conductive by depositing diamond-like carbon (DLC) using vapor deposition. The vias (594) may be occupied with a conductive insert, for example, a brass pin. The vias (594) may be filled with solder. The vias (594) may move liquid solder from an outside surface to the target joint by capillary action. The vias (594) may contain solder to transfer heat to the second pad (592).

A heat source is applied to the first pad (590). Heat is absorbed by the first pad (590) and transmitted by the vias (594) to the second pad (592). The second pad (592) heats up and causes migration of the solder material to between the second pad (592) and the top of the functional component (130). In some examples, the solder liquefies and forms a contact under capillary forces. The assembly (100) then cools, the solder solidifies, and a connection between the functional component (130) and the second circuit board (120) results.

Once cool, the first pad (590), second pad (592), and vias (594) may also function to move heat from the functional component to the external surface of the second circuit board (120). This increases cooling of the functional component and/or other parts on the internal side of the second circuit board (120). For additional discussion of the heat dissipating use of this design approach, see, U.S. Pat. No. 9,386,725, which is incorporated by reference herein.

If the first pad (590), second pad (592), and vias (594) are electrically conductive, for example, they contain metal; the solder may be heated by resistive welding between the functional component (130) and the second pad (592). In some examples, a conductive trace connects the second pad (594) to an edge of the second circuit board (120). A second conductive trace connects the functional component (130) to an edge of the first circuit board (110). Applying a potential between the first and second traces produces a current with a resistance, and the associated heating, between the component (130) and the second pad (592). The resistive welding approach may use a conductive trace instead of the vias (594) and/or first pad (590).

A via (594) is a thermally conductive passage through a circuit board (110, 120). In some cases, the via (594) is metalized, for example, using an immersion placing process. The vias (594) may be thermally conductive due to the presence of solder in the vias (594). Vias (594) are sometimes used to provide electrical pathways through circuit boards (110, 120). However, as shown in this specification, vias (594) may be used to provide thermal pathways, for example, to liquefy solder to attach a component.

It will be appreciated that, within the principles described by this specification, a vast number of variations exist. It should also be appreciated that the examples described are only examples, and are not intended to limit the scope, applicability, or construction of the claims in any way.

What is claimed is:

1. A circuit board assembly, the assembly comprising:
a first circuit board;
a second circuit board; and
a functional component with a first side and a second side opposite the first side, the functional component comprising an electrical pathway between the first circuit board and the second circuit board,
wherein the functional component provides a circuit element in addition to the electrical pathway between the first circuit board and the second circuit board, the first side of the functional component is connected to the first circuit board, the second side of the functional component is connected to the second circuit board, and the functional component mechanically couples the second circuit board.

2. The assembly of claim 1, wherein the functional component is selected from a group consisting of: a capacitor, a surface-mount ferrite, a resistor, and an inductor.

3. The assembly of claim 1, further comprising a plurality of vias passing through the first circuit board wherein the plurality of vias transmit heat from a first side of the functional component.

4. The assembly of claim 1, wherein the functional component comprises a plurality of independent electrical pathways between the first circuit board and the second circuit board.

5. The assembly of claim 1 comprising a plurality of functional components, wherein the functional components of the plurality of functional components are connected to both the first circuit board and the second circuit board.

6. The assembly of claim 5, wherein each of the plurality of functional components provides a circuit element in addition to an electrical pathway between the first circuit board and the second circuit board.

7. The assembly of claim 1, wherein the first side and second side of the functional component each comprise a flat surface, the flat surfaces being parallel to each other.

8. A circuit board assembly, the assembly comprising:
a first circuit board;
a second circuit board; and
a functional component with a first side and a second side opposite the first side, the functional component providing a circuit element other than an electrical pathway between the first circuit board and the second circuit board,
wherein the circuit element is provided to a circuit on the first circuit board, the first side of the functional component is connected to the first circuit board, the second side of the functional component is connected to the second circuit board, and the functional component mechanically couple the second circuit board.

9. The assembly of claim 8, further comprising a plurality of functional components, each of the functional components providing a circuit element other than an electrical pathway between the first circuit board and the second circuit board.

10. The assembly of claim 9, wherein the plurality of functional components include a plurality of types of functional components.

11. A circuit board assembly, the assembly comprising:
a first circuit board;
a second circuit board; and
a plurality of functional components, each functional component mounted to the first circuit board and second circuit board, wherein the functional components mechanically couple the second circuit board and functional components are located at opposite edges of the second circuit board.

12. The assembly of claim 11, wherein the functional components each provide multiple electrical connections between the first circuit board and the second circuit board.

13. The assembly of claim 11, wherein the first circuit board has a lower feature resolution than the second circuit board.

14. The assembly of claim 11, wherein a functional component of the plurality of functional components is accessible through an opening in a circuit board, such that the opening facilitates attachment of the functional component to a circuit board.

15. The assembly of claim 11, wherein the plurality of functional components are directly connected to the second circuit board using selective soldering.
